(19) United States
(12) Patent Application Publication
(10) Pub. No.: US 2026/0169758 A1
(43) Pub. Date: Jun. 18, 2026

(54) QUICK START FOR IEDS

(71) Applicant: Hitachi Energy Ltd, Zürich (CH)

(72) Inventors: Andrei-Marian DAN, Otelfingen (CH); Bernhard DECK, Weilheim (DE); Raphael EIDENBENZ, Zürich (CH); Jakub SIPOWICZ, Kraków (PL)

(21) Appl. No.: 19/126,717

(22) PCT Filed: Nov. 14, 2023
(86) PCT No.: PCT/EP2023/081737

§ 371 Date: May 2, 2025

(30) Foreign Application Priority Data
Nov. 16, 2022 (EP) 22207780.2

(51) Int. Cl. G06F 9/4401; G06F 1/26; H02H 7/26

(52) U.S. Cl. CPC G06F 9/4406; G06F 1/26; H02H 7/26

(57) ABSTRACT

The present disclosure relates to a method for controlling an intelligent electronic device, IED, for power system components, the method comprising: rebooting the IED, wherein rebooting comprises reloading an operating system, executing, while the IED is rebooting, a basic mode of the IED, wherein the basic mode comprises at least one function for protecting a power system component connected to the IED, executing a normal mode, after the operating system is reloaded, wherein the normal mode comprises functions for protecting and controlling the power system component.

The present disclosure in general relates to intelligent electronic devices (IEDs) and in particular to a method for controlling an intelligent electronic device for power system components, an IED for power system components and a corresponding system.

IEDs are restarted during firmware updates, for loading new configurations, or in the presence of power supply failures. The reboot process can last for several minutes, given the growing complexity of the software stack (operating systems, applications, etc.). During this time, the functionality of the IED is not available. This can lead to important damage of the power system components. Due to the increased complexity and security requirements, restarts caused by firmware updates might become more frequent in the future, because the IEDs will receive new security patches more often. Also, with more software running on the IEDs, it will be increasingly necessary to update the software to fix bugs or add new functionality. These updates will likely require restarts of the device.

To eliminate the restarts caused by power supply failures, uninterruptible power supplies are often used in high voltage applications. However, these supplies represent additional system complexity, system costs, as well as additional maintenance and support requirements. This can represent a barrier to adoption in use-cases that require low-cost solutions. Another solution to mitigate the failure of an individual IED during restart is to use redundant devices, providing the same functionality. However, this method still suffers from the problem of the boot time interval when the system is not protected, in the case of a power supply failure.

The present disclosure has thus been made in view of the above problems and challenges and provides increased protection of the power system component(s) and the grid attached to the IED.

The invention is defined in the independent claims. Dependent claims describe preferred embodiments.

The present disclosure relates to a method for controlling an intelligent electronic device, IED, for power system components, the method comprising rebooting the IED, wherein rebooting comprises reloading an operating system, executing, while the IED is rebooting, a basic mode of the IED, wherein the basic mode comprises at least one function for protecting a power system component connected to the IED and executing a normal mode, after the operating system is reloaded, wherein the normal mode comprises functions for protecting and controlling the power system component.

Various embodiments may preferably implement the following features.

Preferably, the method further comprises performing a handover procedure, after the operating system is reloaded, to transfer the functions of the basic mode to the normal mode, wherein the execution of the basic mode is preferably stopped after performing the handover procedure.

Preferably, the power system component is at least one of a circuit breaker, a transformer, a switch/load-break switch, a tap changer, an electric motor, or a capacitor.

Preferably, the basic mode comprises monitoring a physical value of the system component. Preferably, the physical value is at least one of a current, a voltage, a pressure, a temperature, a power, a resistance, or an impedance.

Preferably, the method further comprises triggering a circuit breaker in case the physical value exceeds a predetermined threshold preferably for a predetermined time.

Preferably, the circuit breaker is triggered to take the IED off an energy grid.

Preferably, the method is performed on two entities. The entities may be implemented as software and/or hardware.

Preferably, the method comprises executing the basic mode on a first entity and the normal mode on a second entity.

Preferably, the first and second entities are provided as a single unit, or wherein the first entity is provided as a separate unit from the second entity.

Preferably, the first entity is a first processing unit and the second entity is a second processing unit.

Preferably, the first entity is a hypervisor and the second entity is a virtual machine.

The present disclosure further relates to an intelligent electronic device, IED, for power system components, the IED comprising a processing unit configured to reboot the IED, wherein rebooting comprises reloading an operating system, execute, while the IED is rebooting, a basic mode of the IED, wherein the processing unit is configured to provide at least one function for protecting a power system component connected to the IED in the basic mode, execute a normal mode, after the operating system is reloaded, wherein the processing unit is configured to provide functions for protecting and controlling the power system component in the normal mode.

Preferably, the processing unit is further configured to perform a handover procedure, after the operating system is reloaded, to transfer the functions of the basic mode to the normal mode, wherein processing unit is preferably further configured to stop the execution of the basic mode after performing the handover procedure.

Preferably, IED is configured to be connected to a power system component, wherein the power system component is at least one of a circuit breaker, a transformer, a switch/load-break switch, a tap changer, an electric motor, or a capacitor.

Preferably, the processing unit is further configured to, in the basic mode, monitor a physical value of the system component.

Preferably, the physical value is at least one of a current, a voltage, a pressure, a temperature, a power, a resistance, or an impedance.

Preferably, the processing unit is further configured to trigger a circuit breaker in case the physical value exceeds a predetermined threshold preferably for a predetermined time.

Preferably, the circuit breaker is triggered to take the IED off an energy grid.

Preferably, the processing unit comprises two entities. The entities may be implemented as software and/or hardware.

Preferably, a first entity is configured to execute the basic mode and a second entity is configured to execute the normal mode.

Preferably, the first and the second entity are provided as a single unit, or wherein the first entity is provided as a separate unit from the second entity.

Preferably, the processing unit is a system on chip, SoC, device, wherein the SoC device comprises at least one of a central processing unit, CPU, a digital signal processor, DSP, an image processing unit, or a graphics processing unit, GPU, and the first entity is configured to execute the basic mode on a subset of the SoC. This corresponds to an example of a hardware-based implementation.

Preferably, the first entity is a hypervisor configured to execute the basic mode and the second entity is a virtual machine configured to execute the normal mode. This corresponds to an example of a software-based implementation.

The present disclosure further relates to a system comprising a power system component and an intelligent electronic device, IED, as described above.

The exemplary embodiments disclosed herein are directed to providing features that will become readily apparent by reference to the following description when taken in conjunction with the accompany drawings. In accordance with various embodiments, exemplary systems, methods, devices and computer program products are disclosed herein. It is understood, however, that these embodiments are presented by way of example and not limitation, and it will be apparent to those of ordinary skill in the art who read the present disclosure that various modifications to the disclosed embodiments can be made while remaining within the scope of the present disclosure.

Thus, the present disclosure is not limited to the exemplary embodiments and applications described and illustrated herein. Additionally, the specific order and/or hierarchy of steps in the methods disclosed herein are merely exemplary approaches. Based upon design preferences, the specific order or hierarchy of steps of the disclosed methods or processes can be re-arranged while remaining within the scope of the present disclosure. Thus, those of ordinary skill in the art will understand that the methods and techniques disclosed herein present various steps or acts in a sample order, and the present disclosure is not limited to the specific order or hierarchy presented unless expressly stated otherwise.

The above and other aspects and their implementations are described in greater detail in the drawings, the descriptions, and the claims.

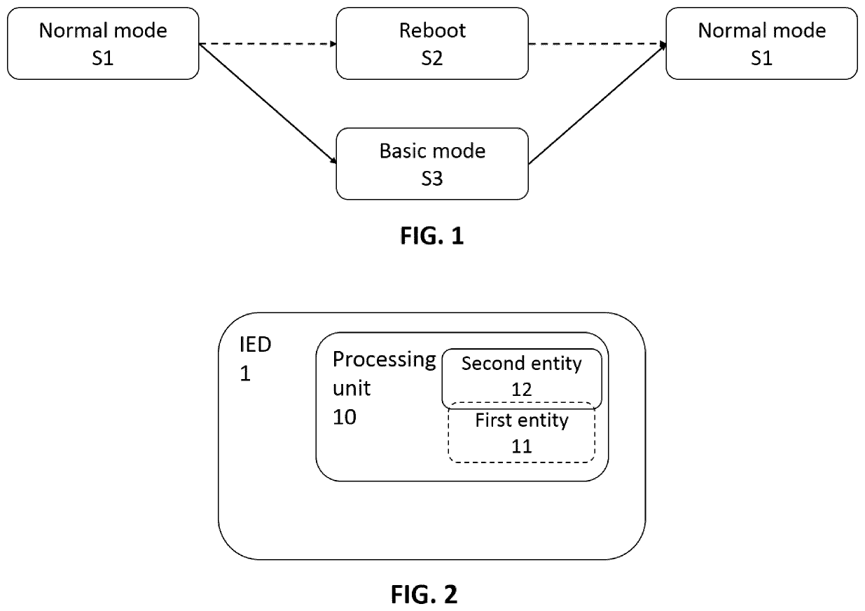

FIG. 1 shows a flowchart of an exemplary method according to the present disclosure.

FIG. 2 shows a schematic diagram of an exemplary IED according to the present disclosure.

The method according to the disclosure, which may also be referred to as a quick start of an IED, enables the IED to start basic control and/or protection functionality (basic mode) without waiting for the entire operating system to be reloaded, in the case of a reboot. In an embodiment, the basic IED mode may be executed outside of the operating system, until the system is completely reloaded.

As used herein, in the basic mode, a minimum protective system may be on duty. In the normal mode, more sophisticated and selective protection and control schemes may be enabled and running. It is noted that the normal mode may cover the functionality of the basic mode.

The method is described with reference to FIG. 1 showing an exemplary flow chart. The method is used for controlling an IED for power system components. In particular, when the IED is running in the normal mode S1, the method comprises rebooting S2 the IED, wherein the rebooting step S2 comprises reloading an operating system. In parallel to the rebooting step S2, the IED executes a basic mode S3 of the IED, wherein the basic mode comprises at least one function for protecting a power system component which is connected to the IED. After the operating system is reloaded, the IED executes the normal mode S1.

In other words, the IED may perform a handover from executing the basic mode S3 (back) to executing the normal mode S1 after the operating system is reloaded and the rebooting step S2 is finished.

The power system component to which the IED is attached may be one of a circuit breaker, a transformer, a switch/load-break switch, a tap changer, an electric motor, or a capacitor. The above list is non-exhaustive and the present disclosure may also be employed for other suitable components.

In general, and as mentioned above, the basic mode may rather relate to functions concerning the protection of the attached system component while the normal mode in addition or alternatively may relate to functions concerning controlling the power system component.

The basic mode may comprise monitoring a physical value of the system component. The physical value may be, e.g., at least one of a current, a voltage, a pressure, a temperature, a power, a resistance, or an impedance, wherein this list is also non-exhaustive. Any value indicative of a potential failure or problem in the energy grid or its respective components may be monitored and processed.

The method may further comprise triggering a circuit breaker in case the physical value exceeds a predetermined threshold. The threshold value may be exceeded for a minimum amount of time (a predetermined time) before taking action, which may also be given as a parameter of the function. In general, the basic mode can monitor any physical value. The triggering function can then consider one or more of the monitored physical values when deciding to trigger/not the circuit breaker to take the IED off the grid and avoid damage to the device.

The normal mode may consist of more complex functions such as functions that require as input the history of the monitored physical values (e.g., directional and distance protection functions). Other examples of complex functions are those that depend on other functions. For instance, the inrush protection functions will block the overcurrent function during the switch on of the transformers. In the normal mode, multiple IEDs may be connected and the collected data, i.e. the measured physical values, may be processed for control and/or protection of each of the IEDs.

The method may be performed on two entities 11, 12. That is, the method may comprise executing the basic mode on a first entity 11 and the normal mode on a second entity 12. The first and second entities 11, 12 may be provided as a single unit, or the first entity 11 may be provided as a separate unit from the second entity 12.

The first entity 11 may be a first processing unit (processor) and the second entity 12 may be a second processing unit (processor). The method may also be performed on a virtual machine, wherein the first entity 11 may be a hypervisor and the second entity 12 may be a virtual machine.

The disclosure also relates to a corresponding IED 1 for power system components. The IED 1 comprises a processing unit 10 configured to execute the method as described above. All functions described in the context of the method are applicable to the IED and vice versa, wherein the processor unit 10 may be configured to execute the respective functions.

Thus, the processing unit 10 is configured to reboot the IED, wherein rebooting comprises reloading an operating system, execute, while the IED 1 is rebooting, a basic mode of the IED 1, wherein the processing unit 10 is configured to provide at least one function for protecting a power system component connected to the IED 1 in the basic mode, and execute a normal mode, after the operating system is reloaded, wherein the processing unit 10 is configured to provide functions for protecting and controlling the power system component in the normal mode.

An exemplary schematic diagram of an IED 1 according to the present disclosure is depicted in FIG. 2. In particular, the IED comprises a processing unit 10 which, in line with the method as explained above, may comprise a first entity 11 and a second entity 12. As indicated by the dashed line of the first entity 11, the first and second entities 11, 12 may be provided as a single unit, or the first entity 11 may be provided as a separate unit from the second entity 12. As non-limiting examples, two ways of implementing the processing unit may be described. As a first example, the processing unit may be a system on chip, SoC, device, wherein the SoC device comprises at least one of a central processing unit, CPU, a digital signal processor, DSP, an image processing unit, or a graphics processing unit, GPU. Multiple elements of a SoC device may be integrated in the same circuit. While the normal mode may utilise the complete SoC device, the basic mode may run on a different processing unit (cf. above) than the normal mode or on a subset of the SoC.

In other words, the normal mode may be executed on a main processing unit (second entity, 12, e.g., the CPU) and the basic mode may run “bare-metal” on a secondary processing unit (first entity 11, e.g., the DSP).

In the event of a system restart, while the main processing unit (second entity 12) is reloading the operating system and the entire software stack, a secondary processing unit (first entity 11) executes “bare-metal” the basic mode. The term “bare-metal” may therein refer to an execution without an operating system. The advantage of bare metal implementation is that it does not require time to load the operating system. Therefore, starting the basic mode may take only a short period of time, e.g. less than one second. During this basic mode, the secondary processing unit may periodically check a flag stored in shared memory. This flag indicates whether the main processing unit restored the entire software stack and is ready to execute in normal mode. Once the system is reloaded, the main unit may set the flag to TRUE, and may resume execution. Optionally, the normal mode (executed on the second entity 12 acting as a main processing unit) takes over the state from the quick-start secondary unit (first entity 11). This state can be available via shared memory. This state memory is also periodically updated by the main processing unit (second entity 12), such that in the event of a system reboot, the quick-start unit (first entity 11) uses this shared state to initialize its functionality.

As a second example, the basic mode may be implemented using a virtual machine. The first entity 11 may be a hypervisor configured to execute the basic mode and the second entity 12 may be a virtual machine configured to execute the normal mode.

A hypervisor, also known as a virtual machine monitor, is the software that creates, runs, and manages virtual machines. In the case of a restart, the hypervisor has an initialization time significantly shorter compared to the entire system load. Therefore, the basic mode logic can run as part of the hypervisor, until the entire virtual machine that provides the normal mode is restored.

When the system restarts, the hypervisor may be very quickly loaded, e.g., in less than one second. The base functionality may be included in the hypervisor and become available, while the virtual machine is being reloaded. Via an internal virtual network, the hypervisor may detect when the virtual machine is restored and hand over the functionality. Subsequently, the normal mode is executed.

The present disclosure also relates to a system comprising a power system component and an intelligent electronic device as described above.

In the present disclosure, a new quick start function for IEDs is provided. By using a basic functionality mode (i.e., basic control and/or protection algorithms) almost immediately after the device restarts and while the operating system is still rebooting, an efficient protection and/or control of a power system component attached to the IED can be ensured. Thereby, damage to the device itself, the power system component and the grid or other devices/elements attached to the IED via the grid may be avoided.

The rest of the functionality (normal mode) becomes available once the entire software stack has been reloaded.

Other aspects, features, and advantages will be apparent from the summary above, as well as from the description that follows, including the figures and the claims.

While various embodiments of the present disclosure have been described above, it should be understood that they have been presented by way of example only, and not by way of limitation. Likewise, the various diagrams may depict an example architectural or configuration, which are provided to enable persons of ordinary skill in the art to understand exemplary features and functions of the present disclosure. Such persons would understand, however, that the present disclosure is not restricted to the illustrated example architectures or configurations, but can be implemented using a variety of alternative architectures and configurations. Additionally, as would be understood by persons of ordinary skill in the art, one or more features of one embodiment can be combined with one or more features of another embodiment described herein. Thus, the breadth and scope of the present disclosure should not be limited by any one of the above-described exemplary embodiments.

It is also understood that any reference to an element herein using a designation such as “first,” “second,” and so forth does not generally limit the quantity or order of those elements. Rather, these designations can be used herein as a convenient means of distinguishing between two or more elements or instances of an element. Thus, a reference to first and second elements does not mean that only two elements can be employed, or that the first element must precede the second element in some manner.

Additionally, a person having ordinary skill in the art would understand that information and signals can be represented using any one of a variety of different technologies and techniques. For example, data, instructions, commands, information, signals, bits and symbols, for example, which may be referenced in the above description can be represented by voltages, currents, electromagnetic waves, magnetic fields or particles, optical fields or particles, or any combination thereof.

A skilled person would further appreciate that any one of the various illustrative logical blocks, units, processors, means, circuits, methods and functions described in connection with the aspects disclosed herein can be implemented by electronic hardware (e.g., a digital implementation, an analog implementation, or a combination of the two), firmware, various forms of program or design code incorporating instructions (which can be referred to herein, for convenience, as “software” or a “software unit”), or any combination of these techniques.

To clearly illustrate this interchangeability of hardware, firmware and software, various illustrative components, blocks, units, circuits, and steps have been described above generally in terms of their functionality. Whether such functionality is implemented as hardware, firmware or software, or a combination of these techniques, depends upon the particular application and design constraints imposed on the overall system. Skilled artisans can implement the described functionality in various ways for each particular application, but such implementation decisions do not cause a departure from the scope of the present disclosure. In accordance with various embodiments, a processor, device, component, circuit, structure, machine, unit, etc. can be configured to perform one or more of the functions described herein. The term “configured to” or “configured for” as used herein with respect to a specified operation or function refers to a processor, device, component, circuit, structure, machine, unit, etc. that is physically constructed, programmed and/or arranged to perform the specified operation or function.

Furthermore, a skilled person would understand that various illustrative logical blocks, units, devices, components and circuits described herein can be implemented within or performed by an integrated circuit (IC) that can include a general purpose processor, a digital signal processor (DSP), an application specific integrated circuit (ASIC), a field programmable gate array (FPGA) or other programmable logic device, or any combination thereof. The logical blocks, units, and circuits can further include antennas and/or transceivers to communicate with various components within the network or within the device. A general purpose processor can be a microprocessor, but in the alternative, the processor can be any conventional processor, controller, or state machine. A processor can also be implemented as a combination of computing devices, e.g., a combination of a DSP and a microprocessor, a plurality of microprocessors, one or more microprocessors in conjunction with a DSP core, or any other suitable configuration to perform the functions described herein. If implemented in software, the functions can be stored as one or more instructions or code on a computer-readable medium. Thus, the steps of a method or algorithm disclosed herein can be implemented as software stored on a computer-readable medium.

In this document, the term “unit” as used herein, refers to software, firmware, hardware, and any combination of these elements for performing the associated functions described herein. Additionally, for purpose of discussion, the various units are described as discrete units; however, as would be apparent to one of ordinary skill in the art, two or more units may be combined to form a single unit that performs the associated functions according embodiments of the present disclosure.

Additionally, memory or other storage, as well as communication components, may be employed in embodiments of the present disclosure. It will be appreciated that, for clarity purposes, the above description has described embodiments of the present disclosure with reference to different functional units and processors. However, it will be apparent that any suitable distribution of functionality between different functional units, processing logic elements or domains may be used without detracting from the present disclosure. For example, functionality illustrated to be performed by separate processing logic elements, or controllers, may be performed by the same processing logic element, or controller. Hence, references to specific functional units are only references to a suitable means for providing the described functionality, rather than indicative of a strict logical or physical structure or organization.

Various modifications to the implementations described in this disclosure will be readily apparent to those skilled in the art, and the general principles defined herein can be applied to other implementations without departing from the scope of the claims. Thus, the disclosure is not intended to be limited to the implementations shown herein, but is to be accorded the widest scope consistent with the novel features and principles disclosed herein, as recited in the claims below.

1. A method for controlling an intelligent electronic device (IED) for power system components, the method comprising:
rebooting the IED, wherein rebooting comprises reloading an operating system,
executing, while the IED is rebooting, a basic mode of the IED, wherein the basic mode comprises at least one function for protecting a power system component connected to the IED,
executing a normal mode, after the operating system is reloaded, wherein the normal mode comprises functions for protecting and controlling the power system component.

2. The method according to claim 1, further comprising performing a handover procedure, after the operating system is reloaded, to transfer the functions of the basic mode to the normal mode.

3. The method according to claim 1, wherein the power system component is at least one of a circuit breaker, a transformer, a switch/load-break switch, a tap changer, an electric motor, or a capacitor.

4. The method according to claim 1, wherein the basic mode comprises monitoring a physical value of the system component.

5. The method according to claim 1, wherein the method is performed on two entities, and wherein the method comprises executing the basic mode on a first entity and the normal mode on a second entity.

6. The method according to claim 5, wherein the first entity is a first processing unit and the second entity is a second processing unit.

7. The method according to claim 5, wherein the first entity is a hypervisor and the second entity is a virtual machine.

8. An intelligent electronic device, (IED) for power system components, the IED comprising a processing unit configured to:
reboot the IED, wherein rebooting comprises reloading an operating system,
execute, while the IED is rebooting, a basic mode of the IED, wherein the processing unit is configured to provide at least one function for protecting a power system component connected to the IED in the basic mode,
execute a normal mode, after the operating system is reloaded, wherein the processing unit is configured to provide functions for protecting and controlling the power system component in the normal mode.

9. The IED according to claim 8, wherein the processing unit is further configured to perform a handover procedure, after the operating system is reloaded, to transfer the functions of the basic mode to the normal mode, wherein the processing unit is preferably further configured to stop the execution of the basic mode after performing the handover procedure.

10. The IED according to claim 8, wherein the IED is configured to be connected to a power system component, wherein the power system component is at least one of a circuit breaker, a transformer, a switch/load-break switch, a tap changer, an electric motor, or a capacitor.

11. The IED according to claim 8, wherein the processing unit is further configured to, in the basic mode, monitor a physical value of the system component,
wherein the physical value is preferably at least one of a current, a voltage, a pressure, a temperature, a power, a resistance, or an impedance; and
the processing unit is preferably further configured to trigger a circuit breaker to take the IED off an energy grid in case the physical value exceeds a predetermined threshold preferably for a predetermined time.

12. The IED according to claim 8, wherein the processing unit comprises two entities and
wherein a first entity is configured to execute the basic mode and a second entity is configured to execute the normal mode,
wherein preferably, the first and the second entity are provided as a single unit, or wherein the first entity is provided as a separate unit from the second entity.

13. The IED according to claim 12, wherein the processing unit is a system on chip (SoC) device, wherein the SoC device comprises at least one of a central processing unit (CPU), a digital signal processor (DSP), an image processing unit, or a graphics processing unit (GPU), and wherein the first entity (11) is configured to execute the basic mode on a subset of the SoC.

14. The IED according to claim 12, wherein the first entity is a hypervisor configured to execute the basic mode and the second entity is a virtual machine configured to execute the normal mode.

15. A system comprising a power system component and an intelligent electronic device (IED), according to claim 8.

16. The method of claim 2, wherein the execution of the basic mode is stopped after performing the handover procedure.

17. The method of claim 4, wherein the physical value is at least one of a current, a voltage, a pressure, a temperature, a power, a resistance, or an impedance.

18. The method of claim 4, wherein the method further comprises triggering a circuit breaker to take the IED off an energy grid in case the physical value exceeds a predetermined threshold for a predetermined time.

19. The method of claim 5, wherein the first and second entities are provided as a single unit.

20. The method of claim 5, wherein the first entity is provided as a separate unit from the second entity.
